(19) United States
(12) Patent Application Publication
(10) Pub. No.: US 2024/0315004 A1
(43) Pub. Date: Sep. 19, 2024

(54) MEMORY STRUCTURE WITH 4F2 OPTIMIZED CELL LAYOUT

(71) Applicant: Applied Materials, Inc., Santa Clara, CA (US)

(72) Inventors: Chang Seok Kang, Santa Clara, CA (US); Sung-Kwan Kang, San Jose, CA (US)

(73) Assignee: Applied Materials, Inc., Santa Clara, CA (US)

(21) Appl. No.: 18/186,091

(22) Filed: Mar. 17, 2023

(51) Int. Cl. H10B 12/00

(52) U.S. Cl. CPC H10B 12/315; H10B 12/03; H10B 12/05; H10B 12/482; H10B 12/488

(57) ABSTRACT

A 4F² two-dimensional dynamic random access memory array may include vertical pillar transistors that are arranged in a honeycomb pattern to maximize the available capacitor footprint on top of the memory array. The bit lines may partially intersect with bottom source/drain regions of two adjacent columns of the vertical transistors, where the columns may be offset based on the honeycomb pattern. The word lines may have a varying width that increases as the word lines enclose the gate regions of the transistors and that decreases between adjacent transistors. The transistor stages may each be formed individually and incrementally, with the bottom source/drain region and the bit lines being completed first, followed by the gate region and the word lines, followed by the top source/drain regions and the capacitors.

### TECHNICAL FIELD

This disclosure generally describes designs for a 4F² two-dimensional dynamic random access memory array. More specifically, this disclosure describes a hexagonal layout for a 4F² memory array with increased bit and word line pitch.

### BACKGROUND

Dynamic random access memory (DRAM) architectures continue to scale down over time. For example, a one transistor, one capacitor (1T-1C) DRAM cell architecture has successfully scaled down from an 8F² size to a 6F² size (where F is the minimum feature size). Designs have been proposed for shrinking the cell size down even further to 4F². However, challenges exist when shrinking the DRAM cell size this dramatically as the feature size continues to decrease. For example, proposed 4F² designs tend to increase leakage current and shrink the pitch between the word lines and the bit lines in the memory array. This leads to isolation difficulties between memory cells and reduces the size of the cell capacitor. Additionally, manufacturing processes are not well adapted to patterning and forming 4F² cells at such a small size. Therefore, improvements in the art are needed.

### SUMMARY

In some embodiments, a two-dimensional (2D) DRAM array may include a plurality of bit lines arranged in a first horizontal direction; a plurality of word lines arranged in a second horizontal direction; and a plurality of transistors arranged in a vertical direction that is orthogonal to the first horizontal direction and the second horizontal direction such that the plurality of bit lines intersect with bottom source/drain regions of the plurality of transistors, and the plurality of word lines intersect with gate regions of the plurality of transistors. The plurality of transistors may be arranged in a honeycomb pattern.

In some embodiments, a 2D DRAM array may include a plurality of bit lines arranged in a first horizontal direction; a plurality of word lines arranged in a second horizontal direction; and a plurality of transistors arranged in a vertical direction that is orthogonal to the first horizontal direction and the second horizontal direction such that the plurality of bit lines intersect with bottom source/drain regions of the plurality of transistors, and the plurality of word lines intersect with gate regions of the plurality of transistors. A pitch for the plurality of bit lines may be greater than 2F, where F is defined as a critical feature size, and a unit cell area for the 2D DRAM array is defined as 4F².

In some embodiments, a method of forming 2D DRAM array may include forming first source/drain regions for a plurality of vertical transistors, and forming a plurality of bit lines that contact the first source/drain regions. The method may also include, after forming the first source/drain regions and the plurality of bit lines, forming gate regions for the plurality of vertical transistors, and forming a plurality of word lines that contact the gate regions. The method may additionally include, after forming the gate regions and the plurality of word lines, forming second source/drain regions for the plurality of vertical transistors, and forming a plurality of capacitors that contact the second source/drain regions.

In any embodiments, any and all of the following features may be implemented in any combination and without limitation. The plurality of bit lines may only partially intersect with the bottom source/drain regions of the plurality of transistors. The array may also include a plurality of spacers between the plurality of bit lines, where the plurality of spacers may also partially intersect with the bottom source/drain regions of the plurality of transistors. A pitch for the plurality of bit lines is greater than 2F. A unit cell area for the 2D DRAM array may be 4F² where F may be defined as a feature size. The array may also include a plurality of capacitors arranged at top source/drain regions of the plurality of transistors, where the plurality of capacitors may have a footprint that is greater than or about

$$\frac{4}{3} π {F}^{2} .$$

The honeycomb pattern may arrange the plurality of transistors such that a transistor in the plurality of transistors may be neighbored by six other transistors. The plurality of word lines may have a nonuniform width such the plurality of bit lines have a nonuniform width within the 2D DRAM array. The plurality of word lines may be thinner between the plurality of transistors than around the plurality of transistors. The array may also include a plurality of spacers between the plurality of word lines, where the plurality of spacers may have a triangular wave pattern. A pitch for the plurality of word lines may be greater than 2F. The gate regions of the plurality of transistors may include epitaxial silicon that may be formed using an epitaxial growth process from a silicon substrate below the plurality of transistors. Forming the first source/drain regions and the plurality of bit lines may include forming a sacrificial layer above a silicon substrate; etching a plurality of holes in the sacrificial layer; forming the first source/drain regions in the plurality of holes; removing the sacrificial layer; forming a bit line material around the first source/drain regions in place of the sacrificial layer; and forming the plurality of bit lines around the first source/drain regions from the bit line material. Forming the gate regions and the plurality of word lines may include forming a sacrificial layer above the first source/drain regions and the plurality of bit lines; etching a plurality of holes in the sacrificial layer that are vertically aligned with the first source/drain regions; forming the gate regions in the plurality of holes; removing the sacrificial layer; forming a word line material around the gate regions; and forming the plurality of word lines around the gate regions from the word line material. Forming the second source/drain regions and the plurality of capacitors may include forming a sacrificial layer over the gate regions and the plurality of word lines; etching a plurality of holes in the sacrificial layer that are vertically aligned with the gate regions; forming the second source/drain regions in the plurality of holes; and forming the plurality of capacitors over the second source/drain regions. The gate regions of the plurality of vertical transistors are formed by selective epitaxial growth.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A-1B illustrate top and perspective views of a conventional 4F² memory array.

FIGS. 2A-2C illustrate top and perspective views of a 4F² memory array with optimized memory cell spacing, according to some embodiments.

FIG. 3 illustrates a flowchart 300 of a method of forming a 2D DRAM array, according to some embodiments.

FIGS. 4A-4Q illustrate incremental stages of a process for forming a 2D DRAM array, according to some embodiments.

### DETAILED DESCRIPTION

This disclosure describes how a 4F² two-dimensional dynamic random access memory array may include vertical pillar transistors that are arranged in a honeycomb pattern to maximize the available capacitor footprint on top of the memory array. The bit lines may partially intersect with bottom source/drain regions of two adjacent columns of the vertical transistors, where the columns may be offset based on the honeycomb pattern. The word lines may have a varying width that increases as the word lines enclose the gate regions of the transistors and that decreases between adjacent transistors. The transistor stages may each be formed individually and incrementally, with the bottom source/drain region and the bit lines being completed first, followed by the gate region and the word lines, followed by the top source/drain regions and the capacitors.

DRAM arrays classified as 4F² are important because they increase the density of DRAM cells in the memory array. However, as the minimum or critical feature size (referred to as “F”) continues to shrink, these existing 4F² memory array designs are becoming increasingly problematic. Specifically, as F approaches 10 nm and smaller, these existing 4F² designs are associated with processing and manufacturing difficulties to achieve high density and small device sizes. These existing 4F² designs may also have performance problems, such as RC delay, higher leakage currents, degraded isolation between memory cells, reduced capacitor sizes, and a floating body effect for the vertical transistors.

The embodiments described in this disclosure propose a more efficient 4F² memory cell layout for vertical 1T-1C DRAM memory cells. Instead of arranging the vertical pillar transistors and capacitors into an orthogonal or rectangular grid, each memory cell area may be defined as a non-rectangular parallelogram. The resulting memory array arranges the vertical memory cells into an offset arrangement that more efficiently spaces the memory cells while still maintaining the 4F² cell area. The offset arrangement of the memory cells yields a larger capacitor area and increases the isolation distance between the capacitors. Additionally, the pitch of the word lines and bit lines may be increased without increasing the cell area. This reduces the RC delay for charging/discharging the memory cell. A processing technique is also described that eliminates many of the problems when manufacturing existing 4F² memory cells.

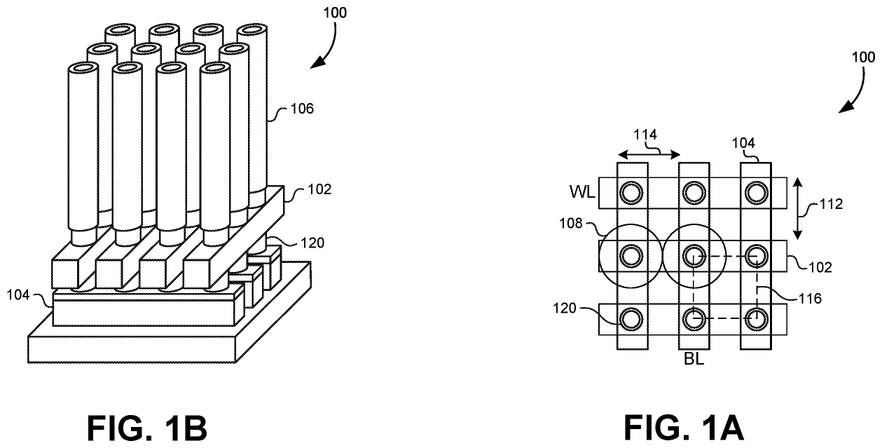

FIGS. 1A-1B illustrate top and perspective views of a conventional 4F² memory array 100. The memory array 100 may include a plurality of word lines 102 that are arranged in a first layer over a substrate. The word lines 102 may be conductive traces that are used to select a word line of memory cells in the memory array 100. The memory array 100 may also include a plurality of bit lines 104 arranged in a second layer over a substrate. The plurality of bit lines may be conductive traces that are used to select a bit line of memory cells in the memory array 100. Activating one of the plurality of bit lines 104 and one of the plurality of word lines 102 may select an individual cell in the memory array 100. The first layer and the second layer may include different metal layers formed at different times during manufacturing process. For example, the first layer with the word lines 102 may be formed above the second layer with the bit lines 104 such that the two layers do not intersect.

A plurality of vertical memory cells may be arranged directly over intersections between the plurality of word lines 102 and the plurality of bit lines 104. Each of the plurality of vertical memory cells may include a vertical transistor, which may be referred to as a vertical pillar transistor. A channel material for the transistor may be formed from a single-crystal silicon pillar. This silicon pillar be formed by etching the substrate. Forming this pillar presents difficulties in controlling the size of the silicon pillar, since the aspect ratio of the etched hole tends to increase as the capacitor diameters and channel diameters decrease. Each of the plurality of vertical memory cells may also include a vertical capacitor 106. The vertical memory cell may operate by storing a charge on the vertical capacitors 106 to indicate a saved memory state.

It is useful to characterize the dimensions of the unit cell area 116 for this conventional 4F² memory array for comparison to the optimized memory array described below. For example, a capacitor footprint 108 may be defined as a circular area around each vertical capacitor 106. The capacitor footprint 108 may include the horizontal cross-sectional area of the capacitor expanded out until the cross-sectional area contacts a capacitor area from a neighboring memory cell. Assuming that the diameter of the vertical capacitors 106 is approximately equal to the critical feature size F. FIG. 1A illustrates that the size of the capacitor footprint 108 may be defined as πF², or the circular cross-section area of the capacitor footprint 108 with a radius of F. The word line pitch for the plurality of word lines 102 and the bit line pitch 114 for the plurality of bit lines 104 may be defined as 2F. This leads to an overall cross-sectional area of 4F² for a unit cell area 116.

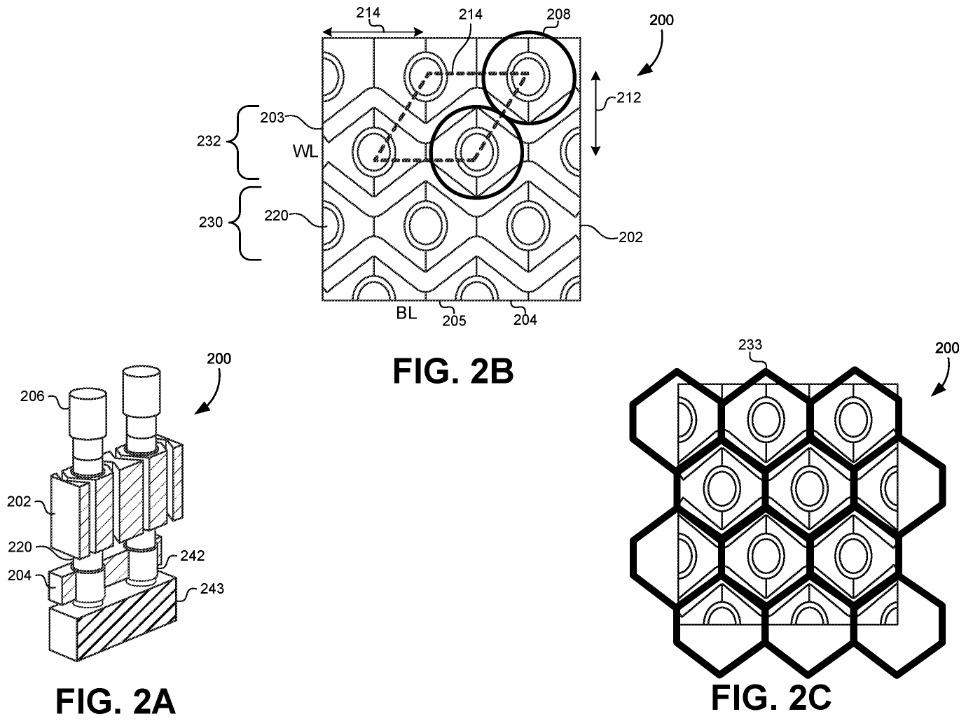

FIGS. 2A-2C illustrate top and perspective views of a 4F² memory array with optimized memory cell spacing, according to some embodiments. The memory array 200 may include a plurality of bit lines arranged in a first horizontal direction. The first horizontal direction may be in a layer or plane that is approximately parallel with an underlying substrate on which the memory array 200 is formed. The memory array 200 may also include a plurality of word lines that are arranged in a second horizontal direction. The second horizontal direction may also be in a layer or plane that is approximately parallel to the underlying substrate and/or the plurality of bit lines. The second horizontal direction may be approximately orthogonal to the first horizontal direction as depicted in FIG. 2B. Additionally, the memory array 200 may include a plurality of transistors, such as vertical transistors or vertical pillar transistors, that are arranged in a vertical direction that is orthogonal to the first and second horizontal directions. Each memory cell in the memory array 200 may include a vertical transistor and a capacitor.

The arrangements of the memory cells in the memory array 200 may be characterized and distinguished from the arrangements of the memory cells in the conventional memory array 100 in a number of different ways. First, the spacing and arrangement of the vertical transistors 220 and capacitors 206 may not follow a rectangular orthogonal grid pattern as in the conventional memory array 100. Instead, the capacitors 206 (along with the vertical transistors 220) may be spaced in alternating rows that are offset by one half the distance between the vertical transistors 220. For example, a first row of memory cells 230 may be regularly spaced in a line in a first direction (e.g., left to right in FIG. 2B). A second row of memory cells 232 may also be regularly spaced in a line also in the first direction, but the second row memory cells 232 may be offset from the first row of memory cells 230. For example, the vertical transistors 220 and capacitors 206 in the second row of memory cells 232 may be aligned halfway between the vertical transistors 220 and capacitors 206 in the first row of memory cells 230 as illustrated in FIG. 2B.

Overall, the capacitors 206 may be arranged in a “honeycomb” pattern as opposed to the orthogonal grid pattern of the conventional memory array 100. This arrangement is illustrated in FIG. 2C with a honeycomb pattern 233 superimposed over the memory array 200. The honeycomb pattern may be arranged such that each memory cell is surrounded or neighbored by six other memory cells. Each memory cell may be enclosed in a virtual hexagonal shape as depicted. Note that the hexagons need not be regular, but may be compressed vertically or horizontally, based on a desired spacing between the memory cells. Other embodiments may use regular hexagons (i.e., with 60° internal angles) for even spacing.

The unit cell areas 216 for the memory array 200 may also be distinguished from the rectangular unit cell areas 116 in the conventional memory array 100. The unit cell area 216 may be defined as one of the hexagons in FIG. 2C. Alternatively, the unit cell area 216 may be defined as the shape made by connecting center points of four adjacent capacitors. As illustrated in FIG. 2B, the shape of the unit cell area 216 may be a non-rectangular parallelogram. Under either definition, the unit cell area may still have an area of 4F². However, the cross-sectional area of the capacitor footprint 208 may be given by the following.

$$Capacitor Area = \frac{4}{3} π {F}^{2}$$

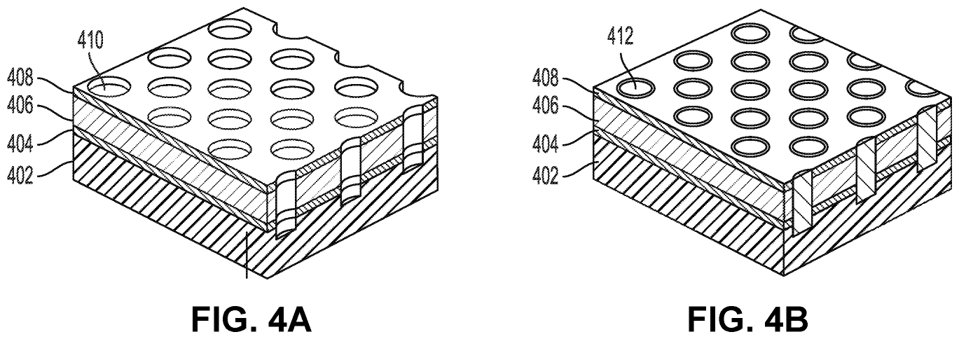

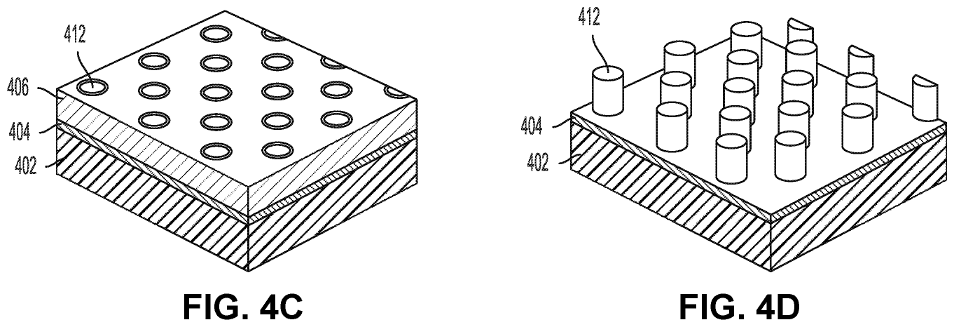

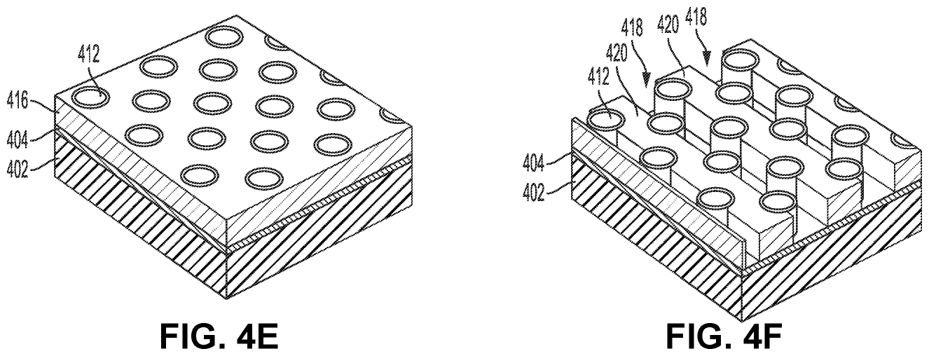

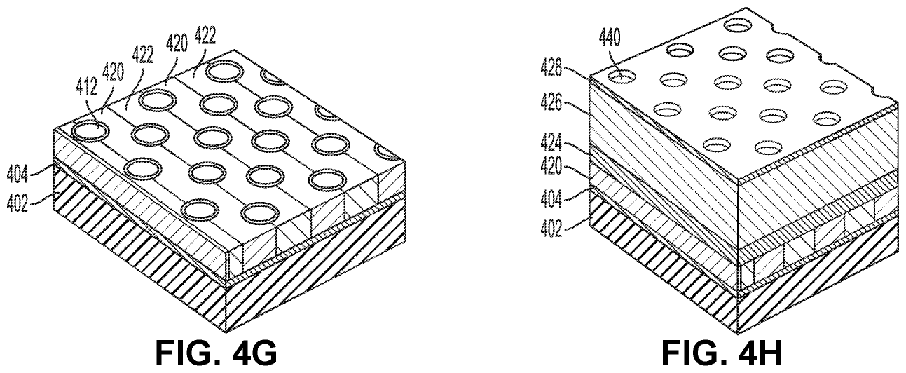

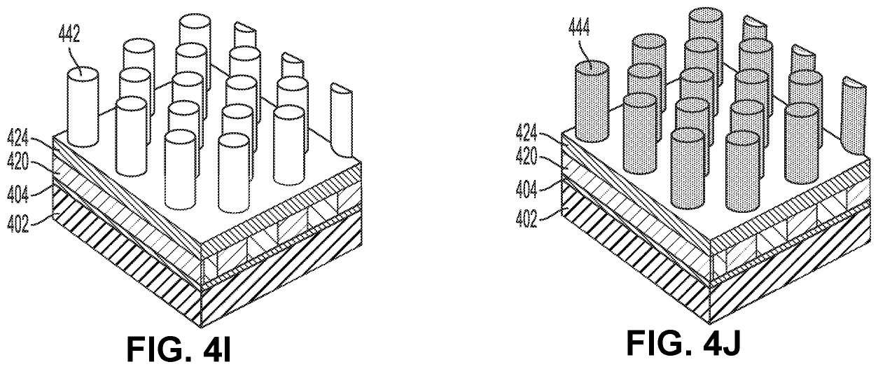

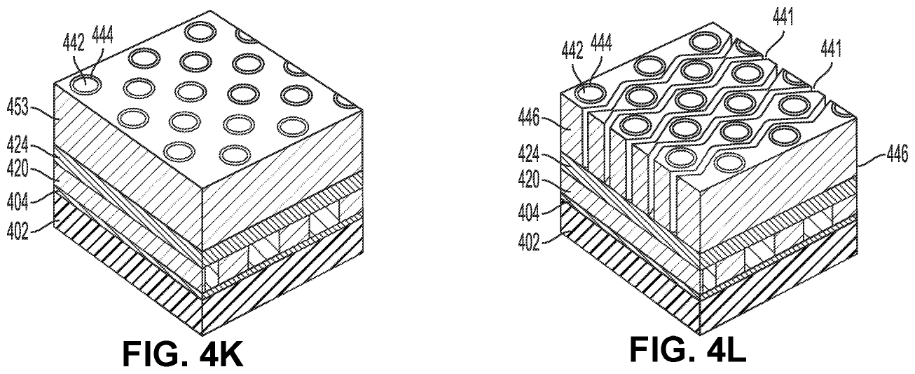

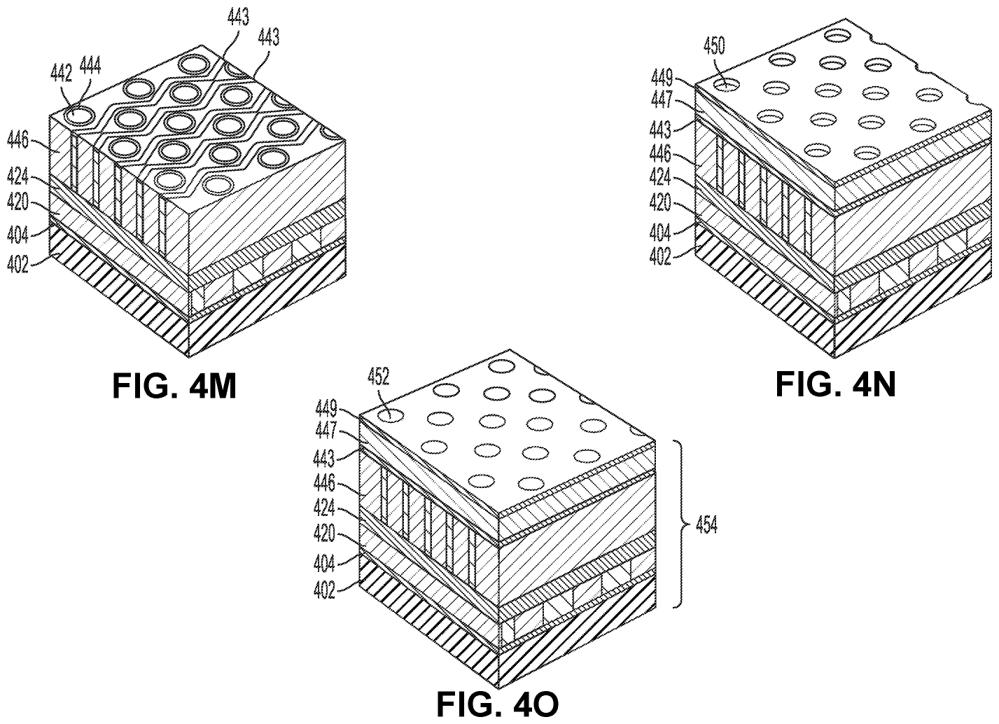

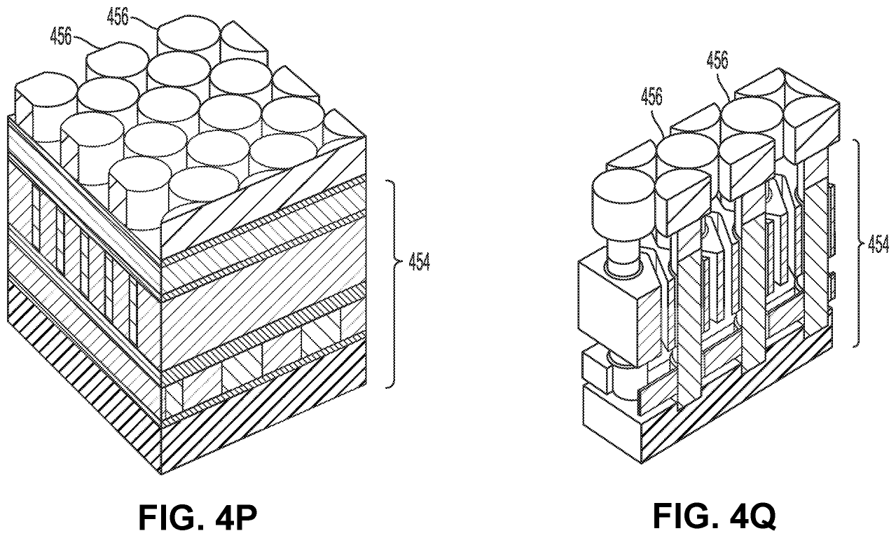

Note that this capacitor footprint 208 is larger than the capacitor footprint 108 of πF² in the conventional memory array 100. The capacitor footprint 208 may be defined as the area in which a capacitor has room to be formed in the memory array 200. These capacitors are shown in FIGS. 4P-4Q below. The capacitor footprint 208 may generally have a larger diameter than the diameter of the vertical transistors 220. However, the capacitor footprint 208 may be limited by the spacing of the vertical transistors 220. The honeycomb arrangement for these embodiments maximizes the available capacitor footprint 208 without increasing the overall size of the unit cell area 216. Therefore, one of the many advantages provided by these embodiments is a larger capacitor area while still maintaining a unit cell area of 4F².

Another way of characterizing the memory array 200 to distinguish it from the conventional memory array 100 is by reference to the alignment of the bit lines 204 relative to the capacitors 206 and vertical pillar for the vertical transistors 220. Specifically, the capacitors 106 and vertical transistors 120 in the conventional memory array 100 are aligned with intersections between the word lines 102 and the bit lines 104. The vertical transistors 120 are completely encased by both the word lines 102 and the bit lines 104 such that these lines entirely intersect rather than only partially intersect with the vertical transistors 120. In contrast, the vertical transistors 220 are misaligned with the bit lines 204 in the memory array 200. Specifically, the bit lines 204 intersect the vertical transistors 220 such that the vertical transistors 220 are only about halfway enclosed by the bit lines 204. For example, in the top view provided by FIG. 2B, the bit lines 204 only partially intersect with two offset columns of transistors 220 (underneath the capacitors 206). Therefore, each of the bit lines 204 may partially intersect two nonaligned columns of transistors. Spacer layers 205 between the bit lines 204 similarly partially intersect the two offset columns of transistors 220. Since the transistors 220 and the capacitors 206 does not create a linear column of transistors 220 in the honeycomb arrangement, the bit lines 204 may instead be formed such that they are wide enough to intersect two of the offset columns of transistors 220. For example, a bit line 204 may intersect a first side of the pillar in the first row of memory cells 230, while intersecting an opposite second side of a pillar in the second row of memory cells 232.

Since the bit lines 204 only need to partially intersect the columns of the vertical transistors 220, this allows the bit line pitch 214 to be greater than the bit line pitch 114 of the conventional memory array 100. Specifically, the bit line pitch 214 may be greater than the 2F bit line pitch 114 of the conventional memory array 100. When the bit lines 204 are aligned with the midpoints of the vertical transistors 220, the bit line pitch may be greater than or about 2.31F. Additionally, the bit lines 204 may be connected with or contact a sidewall of a bottom source/drain connection 242 (e.g., a n-doped source/drain). As will be shown below, the semiconductor pillar for the vertical transistors 220 may also be connected to a substrate 243, which alleviates the “floating body” problem in DRAM transistors where the transistor body is not connected to a voltage, resulting in a floating or unstable body condition.

Another way of characterizing the memory array 200 is by the shape of the spacer layers 203 between the word lines 202. In order to accommodate the offset columns of memory cells, the spacer layers 203 between the word lines may be shaped as a “zigzag” pattern. The spacer layers 203 may also be described as a trianglular pattern, a nonlinear pattern, and/or a wave pattern. The spacer layers 203 may also be characterized as following an approximate contour of the vertical transistors 220. For example, the spacer layers 203 may be drawn such that they maintain at least a minimum distance from each of the vertical transistors 220.

The memory array 200 may also be characterized by the shape of the word lines 202 themselves. For example, the word lines 202 may also be described as nonuniform, or as having a nonuniform width (i.e., the width or distance of the word lines 202 between adjacent rows of the spacer layers 203). The width of the word lines 202 may increase around the vertical transistors 220 to a maximum width aligned with the center of the vertical transistors 220, while decreasing between the vertical transistors 220 to a thinner, minimum width aligned with a midpoint between two adjacent vertical transistors 220 in the same row (e.g., the first row of memory cells 230). The shape of the word lines 202 may also be described as maintaining at least a minimum distance between the vertical transistors 220 and the spacer layers 203 (e.g., at the midpoint of the vertical transistors 220), as well as maintaining at least a minimum distance between adjacent spacer layers 203 (e.g., at the midpoint between adjacent vertical transistors 220). The width of the word lines 202 may be at a maximum at a midpoint of the vertical pillars of each of the vertical transistors 220 and may be at a minimum at a midpoint between the vertical pillars of the vertical transistors 220. This arrangement also increases the word line pitch of the memory array 200 to be greater than the 2F of the conventional memory array 100.

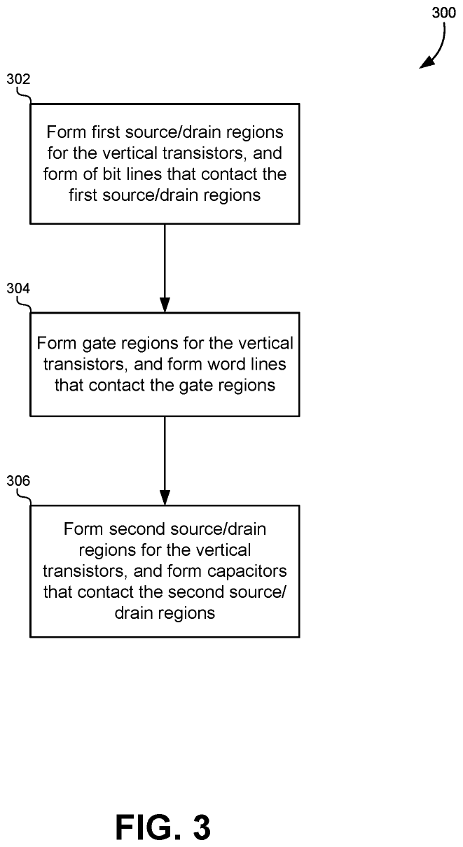

FIG. 3 illustrates a flowchart 300 of a method of forming a 2D DRAM array, according to some embodiments. FIGS. 4A-4Q illustrate incremental stages of a process for forming a 2D DRAM array, according to some embodiments. Examples of each of the operations described in FIG. 3 may be depicted below in FIGS. 4A-4Q. However, these figures are not meant to be limiting on the operations in FIG. 3. Instead, when describing the operations of flowchart 300, reference will be made to the example figures below merely by way of example.

The method may include forming first source/drain regions for a plurality of vertical transistors, and forming a plurality of bit lines that contact the first source/drain regions (302). Overall, this process may incrementally form each stage of the transistor on top of a previous completed stage. For example, the first source/drain regions and bit lines may be formed during a first processing stage, then the gate regions and word lines may be formed during a second processing stage, and the second source/drain regions and capacitors may be formed during a third processing stage, with each processing stage being completed before the next processing stage begins.

FIG. 4A illustrates an first stack deposition with a first hole pattern in the stack. The first stack may be formed on a silicon substrate 402. Above the silicon substrate 402, an etch stop layer 404 may be formed. The etch stop layer 404 may be formed from SiN or other similar materials, and may be between about 2 nm and about 20 nm thick, with thickness being measured in the vertical direction depicted in the figures. A sacrificial layer 406 may be formed bove the etch stop layer 404. The sacrificial layer 406 may be formed from SiO or other similar materials, and may be between about 5 nm and about 50 nm thick. Above the sacrificial layer 406, a chemical-mechanical polishing (CMP) stop layer 408 may be formed. The CMP stop layer 408 may be formed from silicon nitride or other similar materials, and may be between about 2 nm and about 20 nm thick. These layers may be formed using various processes, such as damascene processes, deposition processes, and so forth.

The surface of the stack may be patterned with a first hole pattern as depicted in FIG. 4A. These holes may represent the pattern for the transistor pillars for the vertical transistors. As illustrated, these holes 410 may be patterned in a honeycomb pattern as described above. The holes may be patterned using a lithography process and then etched to form the holes 410. The critical dimension (CD) for the holes 410 may be between about 5 nm and about 15 nm when F is about 10 nm (i.e., between about 0.5F and about 1.5F relative to the critical feature size F). Note that the holes 410 may be etched down at least to a level of the silicon substrate 402. For example, the holes 410 may be etched to at least expose a top surface of the silicon substrate 402. In some embodiments, the holes 410 may be etched to a level that is below the top surface of the silicon substrate 402. This allows the silicon pillars for the vertical transistors to be connected to the silicon substrate 402 and/or grown from the silicon substrate as described below.

FIG. 4B illustrates how the holes 410 may be filled with pillar material 412. For example, a number of different materials may be used for the pillar material 412 used for the vertical pillars of the transistors based on this process. For example, the pillar material 412 may include a crystalline semiconductor, such as silicon, germanium, silicon germanium, and/or other similar materials. These materials may also be used in a polycrystalline semiconductor form. In some embodiments, a metal oxide semiconductor material may be used for the pillar material 412, such as indium gallium zinc oxide (IGZO). In some embodiments, the pillar material 412 may be formed by epitaxially growing epitaxial silicon in the holes 410. The silicon substrate 402 may be used as a bed for growing the epitaxial silicon in the holes 410 for a selective epitaxial growth (SEG) process. Alternatively, the pillar material 412 may be formed by conformally filling the holes 410 with polycrystalline semiconductor layers.

FIG. 4C illustrates the result of a planarization process to remove any overburden caused by filling the holes 410 with the pillar material 412. Growing or forming the pillar material 412 may cause the pillar material 412 to extend above the tops of the holes 410. In order to create a level and uniform height for the pillar material 412, the stack may undergo a planarization process, such as a CMP process to remove the top portion of the stack. For example, the planarization process may remove any overburden of the pillar material 412, as well as the CMP stop layer 408 until the sacrificial layer 406 is exposed.

FIG. 4D illustrates a removal of the sacrificial layer 406. The sacrificial layer 406 may be removed using a selective etch process. Note that SiO of the sacrificial layer 406 has a high selectivity relative to the SiN of the etch stop layer 404. These materials are used only by way of example and are not meant to be limiting. Other materials may be used that have a sufficient selectivity difference for the etch process. The etch process may include wet etch processes or dry etch processes. For example, a wet etch process using dilute HF may be used to selectively remove the SiO.

After the sacrificial layer 406 is removed, the surface of the pillar material 412 may be doped to form a source/drain region and a contact for the bit lines. For example, an N-type dopant may be used to doped the surface of the silicon pillars. Dopants may include phosphorus, arsenic, and/or other similar materials. In some embodiments, the doping concentration may be between about 1e19 cm³ and about 1e21 cm³. The depth of the resulting N+ regions may range from about 1 nm to about 7 nm deep in the pillar material 412.

FIG. 4E illustrates the formation of a bit line material 416 that may be used for the bit lines in the memory cell. After the doping process described above, the bit line material 416 may be formed to cover the etch stop layer 404. Some embodiments may also form a barrier layer using a barrier material such as titanium nitride or tantalum nitride. The barrier layer may be formed before the bit line material 416 is formed. The bit line material 416 may be formed using any type of deposition process. The bit line material 416 may include N+polysilicon, titanium, molybdenum, ruthenium, iridium, and/or other similar materials. In some cases, the bit line material 416 may be formed such that the bit line material 416 extends above or even covers the pillar material 412. Therefore, the process may also include performing another planarization process, such as a CMP process that removes any overburden of the bit line material 416 down to a level of the pillar material 412.

FIG. 4F illustrates the patterning and formation of individual bit lines 420 in the bit line material 416. The patterning process may be performed using any lithography process and the bit line material 416 may be selectively etched relative to the etch stop layer 404. For example, a SiO mask may be used to selectively pattern and/or etch the bit lines 420. The bit line material 416 may be removed down to the etch stop layer 404. As described above, each of the bit lines 420 may intersect to offset columns of the pillar material 412. The bit lines 420 may intersect the pillar material 412 at approximately a midpoint of the pillar material 412 for each vertical transistor. In other embodiments, the intersection be increased or decreased to intersect with more than half or less than half of the pillar material 412 for each vertical transistor. The selective etch may leave voids 418 between the bit lines 420 to be filled with an insulating material.

FIG. 4G illustrates an insulating material 422 between the bit lines 420. The insulating material 422 may correspond to the spacer layers 205 in FIG. 2B. The insulating material 422 may isolate the bit lines 420 from each other. In some embodiments, the width of the insulating material 422 may be approximately equal to the width of the bit lines 420. Other embodiments may allow for wider or narrower lines of insulating material 422, corresponding to narrower or wider bit lines 420. The insulating material 422 may be implemented using any insulator, such as SiO. At this stage, the bit lines 420 are formed, isolated, and placed such that the bit lines 420 intersect with the source/drain regions formed by the pillar material 412 for each of the vertical transistors.

Turning back briefly to FIG. 3, the method may also include forming gate regions for the plurality of vertical transistors, and forming a plurality of word lines that contact the gate regions (304). Note that this second processing stage may take place after forming the first source/drain regions and the plurality of bit lines. For example, the gate regions and word lines may be formed on top of a flat surface that includes the completed first source/drain regions and the plurality of bit lines. As described below, the gate regions may be formed such that they directly line up with the first source/drain regions from the first processing stage.

FIG. 4H illustrates a second stack deposition process used to form the channels for the vertical transistors over the source drain regions. An etch stop layer 424 may be formed using SiN or other similar materials having a thickness of between about 2 nm and about 20 nm. A sacrificial layer 426 may be formed using SiO or other similar materials having a high etch selectivity relative to the etch stop layer 424. The sacrificial layer 426 may have a thickness of between about 20 nm and about 1000 nm. A CMP stop layer 428 may be formed using SiN or other similar materials, and may have a thickness of between about 2 nm and about 20 nm. These layers may be formed as described above in FIG. 4A. Similarly, holes 440 may be patterned using the same pattern described above in FIG. 4A such that the holes 440 are aligned above the pillar material 412 forming the source/drain regions described above. Multiple etch processes may be used to form the holes 440, where each etch process is selective for the CMP stop layer 428, the sacrificial layer 426, and the etch stop layer 424. For example, a series of SiN/SiO/SiN etch processes may be used. As described above, the CD ranges for the holes 440 may be about 0.5F to about 1.5F.

FIG. 4I illustrates the formation of the channels for the vertical transistors. As described above in FIGS. 4B-4D, the holes 440 may be filled using a number of different processes and/or materials. For example, the channel material 442 may be formed from epitaxial silicon using an SEG process. The channel material 442 may include a conformal filling of polysilicon semiconductor layers in the holes 440. The filling material may include Si, Ge, SiGe, metal oxides such as IGZO, and/or other suitable materials. A planarization process may be performed to remove the CMP stop layer 428 along with any overburden of the channel material 442 extending above the holes 440. This may create a uniform height among all of the channels for the vertical transistors. The sacrificial layer 426 may then be removed down to the etch stop layer 424 to expose the vertical pillars for the channels formed by the channel material 442.

FIG. 4J illustrates the formation of a gate oxide 444 around each of the vertical pillars formed by the channel material 442. The gate oxide 444 may be formed from materials such as SiO or other similar materials. For example, SiO may be oxidized from the vertical pillars of the pillar material 412 to be used as the gate oxide 444. The thickness of the gate oxide may be between about 1 nm and about 10 nm. Although not shown explicitly in FIG. 4J due to size constraints, a gate metal may also be formed on the gate oxide 444.

FIG. 4K illustrates the formation of a word line material 453. The word line material 453 may be formed from any of the materials described above performing the bit lines 420. For example, the word line material 453 may be formed from tungsten, molybdenum, and other similar conductors. As with the bit line material 416 described above, the word line material 453 may be formed such that it extends beyond or over the channel material 442. A planarization process may be performed to remove any overburden of the word line material 453. As illustrated in FIG. 4K, the planarization process may also remove the gate oxide 444 from the top of the channel pillars to expose the channel material 442.

FIG. 4L illustrates the formation of the word lines 446. As described above for the process for forming the bit lines 420, a pattern or mask defining the spacer layers 203 and FIG. 2B may be used to form the voids 441 between the word lines 446 formed by an etch process. As described above, these voids 441 may have a triangular, zigzag, or wave pattern with a uniform width. The resulting word lines 446 may have a nonuniform width that increases as the word lines 446 surround the channel material 442, and that decreases as the word lines 446 are routed between adjacent pillars of channel material 442 within a row of memory cells. The voids 441 may serve to isolate neighboring word lines.

FIG. 4M illustrates the formation of the spacer layers 203 from FIG. 2B between the word lines 446. The spacer layers may be formed from any insulating material 443, such as SiO, dielectrics, or other similar materials. In some embodiments, a planarization process may be performed to create a flat surface at the top of the stack for the formation of subsequent layers.

Turning back briefly to FIG. 3, the method may also include forming second source/drain regions for the plurality of vertical transistors, and forming a plurality of capacitors that contact the second source/drain regions (306). Note that this third processing stage may take place after forming the gate regions and the plurality of word lines. For example, the second source/drain regions may be formed on top of a flat surface that includes the completed gate regions and the plurality of word lines. As described below, the second source/drain regions may be formed such that they directly line up with the gate regions from the first processing stage.

FIG. 4N illustrates a third stack deposition process. The third stack deposition process may be carried out in a manner that is similar to the first and/or second stack deposition processes described above. For example, an etch stop layer 443 (e.g., SiN) may be formed with a thickness of about 2 nm to about 20 nm. A sacrificial layer 447 (e.g., SiO) may be formed with a thickness of about 2 nm to about 20 nm. A CMP stop layer 449 (e.g., SiN) may be formed with a thickness of about 2 nm to about 20 nm. Holes 450 may be patterned and etched down through the etch stop layer 443 to expose the channel material 442 from the underlying layers. The etch process may be selected to each of the etch stop layer 443, the sacrificial layer 447, and the CMP stop layer 449 in succession. The holes 450 may be sized as described above to conform with the existing vertical transistor pillars.

FIG. 40 illustrates the formation of the source/drain regions at the top of the vertical transistors. The holes 450 may be filled with a pillar material 452 as described above for the bottom source/drain regions. For example, the pillar material 452 may be formed from epitaxial silicon that is doped with phosphorus, arsenic, or other similar materials through an implant process. In some embodiments, the stack 454 may then be planarized to create a level surface. At this stage, the pillar material 412, the channel material 442, and the pillar material 452 may form a continuous and uniform vertical pillar for the vertical transistor, even though each portion of the pillar was fabricated individually in different processing stages.

FIG. 4P and FIG. 4Q illustrate the formation of the capacitors 456 on top of the vertical transistors as part of each individual memory cell. The capacitors 456 may be formed using conventional techniques, such as forming a bottom electrode, forming a dielectric, and forming a top electrode. Note that the capacitor footprint of the capacitors 456 is maximized and is generally larger in diameter than the diameter of the corresponding vertical transistors.

It should be appreciated that the specific steps illustrated in FIG. 3 provide particular methods of forming a 2D DRAM array according to various embodiments. Other sequences of steps may also be performed according to alternative embodiments. For example, alternative embodiments may perform the steps outlined above in a different order. Moreover, the individual steps illustrated in FIG. 3 may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A two-dimensional (2D) dynamic random access memory (DRAM) array comprising:
a plurality of bit lines arranged in a first horizontal direction;
a plurality of word lines arranged in a second horizontal direction; and
a plurality of transistors arranged in a vertical direction that is orthogonal to the first horizontal direction and the second horizontal direction such that the plurality of bit lines intersect with bottom source/drain regions of the plurality of transistors, and the plurality of word lines intersect with gate regions of the plurality of transistors;
wherein the plurality of transistors are arranged in a honeycomb pattern.

2. The 2D DRAM array of claim 1, wherein the plurality of bit lines only partially intersect with the bottom source/drain regions of the plurality of transistors.

3. The 2D DRAM array of claim 2, further comprising a plurality of spacers between the plurality of bit lines, wherein the plurality of spacers also partially intersect with the bottom source/drain regions of the plurality of transistors.

4. The 2D DRAM array of claim 1, wherein a pitch for the plurality of bit lines is greater than 2F, where F is defined as a feature size, and a unit cell area for the 2D DRAM array is defined as 4F².

5. The 2D DRAM array of claim 1, wherein a unit cell area for the 2D DRAM array is 4F² where F is defined as a feature size, and the unit cell area is defined as a non-rectangular parallelogram or as a hexagon in the honeycomb pattern.

6. The 2D DRAM array of claim 1, further comprising a plurality of capacitors arranged at top source/drain regions of the plurality of transistors, wherein the plurality of capacitors have a footprint that is
$$\frac{4}{3} π {F}^{2}$$
where r is defined as a feature size.

7. The 2D DRAM array of claim 1, wherein the honeycomb pattern arranges the plurality of transistors such that a transistor in the plurality of transistors is neighbored by six other transistors.

8. A two-dimensional (2D) dynamic random access memory (DRAM) array comprising:
a plurality of bit lines arranged in a first horizontal direction;
a plurality of word lines arranged in a second horizontal direction; and
a plurality of transistors arranged in a vertical direction that is orthogonal to the 5 first horizontal direction and the second horizontal direction such that the plurality of bit lines intersect with bottom source/drain regions of the plurality of transistors, and the plurality of word lines intersect with gate regions of the plurality of transistors;
wherein a pitch for the plurality of bit lines is greater than 2F, where F is defined as a feature size, and a unit cell area for the 2D DRAM array is defined as 4F².

9. The 2D DRAM array of claim 8, wherein the plurality of word lines have a nonuniform width such the plurality of bit lines have a nonuniform width within the 2D DRAM array.

10. The 2D DRAM array of claim 9, wherein the plurality of word lines are thinner between the plurality of transistors than around the plurality of transistors.

11. The 2D DRAM array of claim 8, wherein the plurality of transistors are arranged in a honeycomb pattern.

12. The 2D DRAM array of claim 8, further comprising a plurality of spacers between the plurality of word lines, wherein the plurality of spacers have a triangular wave pattern.

13. The 2D DRAM array of claim 8, wherein a pitch for the plurality of word lines is greater than 2F.

14. The 2D DRAM array of claim 8, wherein the gate regions of the plurality of transistors comprise epitaxial silicon that is formed using an epitaxial growth process from a silicon substrate below the plurality of transistors.

15. A method of forming two-dimensional (2D) dynamic random access memory (DRAM) arrays, the method comprising:
forming first source/drain regions for a plurality of vertical transistors, and forming a plurality of bit lines that contact the first source/drain regions;
after forming the first source/drain regions and the plurality of bit lines, forming gate regions for the plurality of vertical transistors, and forming a plurality of word lines that contact the gate regions; and
after forming the gate regions and the plurality of word lines, forming second source/drain regions for the plurality of vertical transistors, and forming a plurality of capacitors that contact the second source/drain regions.

16. The method of claim 15, wherein the plurality of vertical transistors are arranged in a honeycomb pattern.

17. The method of claim 15, wherein forming the first source/drain regions and the plurality of bit lines comprises:
forming a sacrificial layer above a silicon substrate;
etching a plurality of holes in the sacrificial layer;
forming the first source/drain regions in the plurality of holes;
removing the sacrificial layer;
forming a bit line material around the first source/drain regions in place of the sacrificial layer; and
forming the plurality of bit lines around the first source/drain regions from the bit line material.

18. The method of claim 15, wherein forming the gate regions and the plurality of word lines comprises:
forming a sacrificial layer above the first source/drain regions and the plurality of bit lines;
etching a plurality of holes in the sacrificial layer that are vertically aligned with the first source/drain regions;
forming the gate regions in the plurality of holes;
removing the sacrificial layer;
forming a word line material around the gate regions; and
forming the plurality of word lines around the gate regions from the word line material.

19. The method of claim 15, wherein forming the second source/drain regions and the plurality of capacitors comprises:
forming a sacrificial layer over the gate regions and the plurality of word lines;
etching a plurality of holes in the sacrificial layer that are vertically aligned with 4 the gate regions;
forming the second source/drain regions in the plurality of holes; and
forming the plurality of capacitors over the second source/drain regions.

20. The method of claim 15, the gate regions of the plurality of vertical transistors are formed by selective epitaxial growth.
